(19) United States
(12) Patent Application Publication
(10) Pub. No.: US 2023/0024544 A1
(43) Pub. Date: Jan. 26, 2023

(54) SEMICONDUCTOR STRUCTURE, METHOD OF FORMING SEMICONDUCTOR STRUCTURE, AND MEMORY

(71) Applicant: CHANGXIN MEMORY TECHNOLOGIES, INC., Hefei City (CN)

(72) Inventor: Shuangshuang WU, Hefei City (CN)

(73) Assignee: CHANGXIN MEMORY TECHNOLOGIES, INC., Hefei City (CN)

(21) Appl. No.: 17/648,675

(22) Filed: Jan. 23, 2022

Related U.S. Application Data
(63) Continuation of application No. PCT/CN2021/118803, filed on Sep. 16, 2021.

(30) Foreign Application Priority Data
Jul. 20, 2021 (CN) 202110819890.9

(51) Int. Cl. H01L 23/532; H01L 21/768

(52) U.S. Cl. CPC H01L 23/53295; H01L 21/76832

(57) ABSTRACT

A semiconductor structure includes: a base; a first conductive layer, having a portion located within the base and a remaining portion protruding above the base; a barrier layer on the base and at least on a sidewall of the first conductive layer protruding from the base; a dielectric layer on the barrier layer; and a second conductive layer penetrating the dielectric layer and the barrier layer, in contact with the sidewall of the barrier layer, and in contact with at least a portion of the upper surface of the first conductive layer.

### CROSS-REFERENCE TO RELATED APPLICATIONS

This is a continuation of an International Patent Application No. PCT/CN2021/118803 filed on Sep. 16, 2021, which claims priority to Chinese Patent Application No. 202110819890.9 filed on Jul. 20, 2021. The disclosures of the above-referenced applications are hereby incorporated by reference in their entirety.

### BACKGROUND

With the rapid development of integrated circuit technology, the density of devices in an integrated circuit is getting higher and higher, the characteristic size of a semiconductor device is decreasing, and the electrode area of a semiconductor structure is decreasing. During a fabrication process, metal interconnection structures may be fabricated on electrodes for wiring or test. The introduction of a metal interconnection structure can not only increase the device integration and speed, but also reduce the chip cost and simplify the device fabrication process.

### SUMMARY

The present disclosure relates, but are not limited, to a semiconductor structure, a method of forming a semiconductor structure, and a memory.

According to some embodiments of the present disclosure, an aspect of the embodiments in the present disclosure provides a semiconductor structure. The semiconductor structure includes: a base; a first conductive layer, having a portion located within the base and a remaining portion protruding above the base; a barrier layer on the base, barrier layer being at least on a sidewall of the first conductive layer protruding from the base; a dielectric layer on the barrier layer; and a second conductive layer penetrating the dielectric layer and the barrier layer, being in contact with the sidewall of the barrier layer and being in contact with at least a portion of an upper surface of the first conductive layer.

According to some embodiments of the present disclosure, another aspect of the embodiments in the present disclosure further provides a method of forming a semiconductor structure. The method includes: providing a base; forming a first conductive layer that has a portion located within the base and a remaining portion of the first conductive layer protruding above the base; forming a barrier layer, the barrier layer being on the base and at least on a sidewall of the first conductive layer protruding from the base; forming a dielectric layer covering a surface of the barrier layer; and forming a second conductive layer that penetrates the dielectric layer and the barrier layer, is in contact with the sidewall of the barrier layer and is in contact with at least a portion of an upper surface of the first conductive layer.

According to some embodiments of the present disclosure, yet another aspect of the present disclosure further provides a memory including the semiconductor structure according to any aspect described above.

### BRIEF DESCRIPTION OF THE DRAWINGS

In order to more clearly explain the technical solutions in the embodiments of the present disclosure or the conventional technology, the accompanying drawings required in the description of the embodiments or the conventional technology will be briefly described below. Obviously, the accompanying drawings in the description below are merely some embodiments of the present disclosure, and other drawings may be obtained from these drawings without creative effort for those of ordinary skill in the art.

FIG. 1 illustrates a schematic diagram of a semiconductor structure.

FIG. 2 illustrates a schematic diagram of a semiconductor structure according to an embodiment of the present disclosure.

FIG. 3 illustrates a schematic diagram of another semiconductor structure according to an embodiment of the present disclosure.

FIG. 4 illustrates a first schematic diagram of an operation of a method of forming a semiconductor structure according some embodiments of the present disclosure.

FIG. 5 illustrates a second schematic diagram of an operation of a method of forming a semiconductor structure according some embodiments of the present disclosure.

FIG. 6 illustrates a third schematic diagram of an operation of a method of forming a semiconductor structure according some embodiments of the present disclosure.

FIG. 7 illustrates a fourth schematic diagram of an operation of a method of forming a semiconductor structure according some embodiments of the present disclosure.

FIG. 8 illustrates a fifth schematic diagram of an operation of a method of forming a semiconductor structure according some embodiments of the present disclosure.

FIG. 9 illustrates a sixth schematic diagram of an operation of a method of forming a semiconductor structure according some embodiments of the present disclosure.

FIG. 10 illustrates a seventh schematic diagram of an operation of a method of forming a semiconductor structure according some embodiments of the present disclosure.

FIG. 11 illustrates an eighth schematic diagram of an operation of a method of forming a semiconductor structure according some embodiments of the present disclosure.

### DETAILED DESCRIPTION

A barrier layer plays a key role in a metal interconnection structure, which directly affects the performance of a device. In process of processing the metal interconnection structure, after multi-operation processing, the contact surface of different conductive layers may become uneven. A contact area between a barrier layer and a different conductive layer can be small, and the adhesion effect between the barrier layer and the conductive layer is not good. In a subsequent processing process, different conductive layers may be separated from each other, which affects the performance of the semiconductor structure.

That is, the contact effect between different conductive layers of a semiconductor structure can be poor.

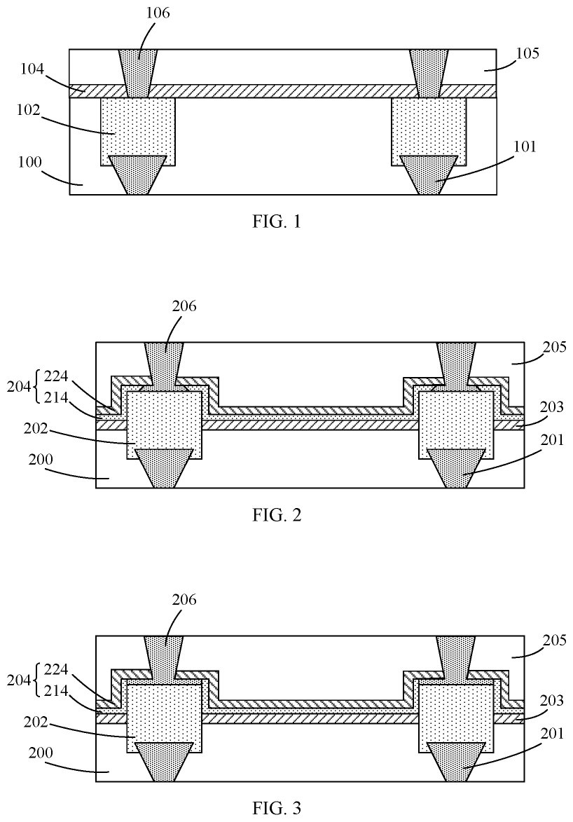

The specific description will be given in combination with a semiconductor structure. Referring to FIG. 1, the semiconductor structure includes: a base 100 having an electrode 101 therein; a first conductive layer 102 located within the base 100 and in contact with the electrode 101; a barrier layer 104 on the base 100 and on a top surface of the first conductive layer 102 exposed from the base 100; a dielectric layer 105 located on the barrier layer 104; a second conductive layer 106 penetrating the dielectric layer 105 and the barrier layer 104. The second conductive layer 106 is in contact with the sidewall of the barrier layer 104, and the second conductive layer 106 is in contact with a portion of an upper surface of the first conductive layer 102.

It may be obtained that the barrier layer 104 is located only on part of the upper surface of the first conductive layer 102, and a contact area between the barrier layer 104 and the first conductive layer 102 is small, resulting in a poor adhesion and fixing effect between the first conductive layer 102 and the barrier layer 104. Since the barrier layer 104 and a bottom surface of the second conductive layer 106 are on a same horizontal level, when the location of the second conductive layer 106 changes due to process stress in a subsequent processing process, a location change direction of the barrier layer 104 under the process stress is the same as a location change direction of the second conductive layer 106, and the barrier layer 104 cannot contribute to fixing the second conductive layer 106.

The embodiments of the present disclosure provide a semiconductor structure in which a barrier layer is not only in contact with a sidewall of a first conductive layer protruding from a base, but also in contact with a sidewall of a second conductive layer, so that the same barrier layer is in contact with different conductive layers, which is conducive to fixing locations of different conductive layers by use of the barrier layer, and in a subsequent process, a location relationship between the different conductive layers is not easily affected by stress to form a gap. Meanwhile, the contact between the barrier layer and the sidewall of the conductive layer is beneficial to an increase in the contact area. The larger the contact area, the better the adhesion and fixing effect of the barrier layer to the conductive layer.

Various embodiments of the present disclosure will be described in detail below with reference to the accompanying drawings. However, those of ordinary skill in the art will appreciate that many technical details have been proposed in various embodiments of the present disclosure for better understanding of the present disclosure. However, the technical solutions described in the present disclosure may be realized even without these technical details as well as various changes and modifications according to the following embodiments.

FIG. 2 illustrates a schematic diagram of a semiconductor structure according to an embodiment of the present disclosure.

Referring to FIG. 2, the semiconductor structure includes: a base 200; a first conductive layer 202, having a portion located within the base 200 and a remaining portion protruding above the base 200; a barrier layer 204 on the base 200 and at least on a sidewall of the first conductive layer 202 protruding from the base 200; a dielectric layer 205 on the barrier layer 204; and a second conductive layer 206 penetrating the dielectric layer 205 and the barrier layer 204. The second conductive layer 206 is in contact with the sidewall of the barrier layer 204, and the second conductive layer 206 is in contact with at least a portion of an upper surface of the first conductive layer 202.

A barrier layer 204 is not only in contact with the sidewall of the first conductive layer 202 protruding from the base 200, but also in contact with a sidewall of the second conductive layer 206, so that the same barrier layer 204 are in contact with different conductive layers, which is conducive to fixing locations of different conductive layers by use of the barrier layer 204, and in a subsequent process, the location relationship between the different conductive layers is not easily affected by stress to form a gap which affects the performance of the semiconductor structure. Meanwhile, the contact between the barrier layer 204 and the sidewalls of the conductive layers is beneficial to an increase in the contact area. The larger the contact area, the better the adhesion and fixing effect of the barrier layer 204 to the conductive layers.

Hereinafter, the embodiments of the present disclosure will be described in more detail with reference to the accompanying drawings.

The material of the base 200 is an isolation material for isolating a conductive layer from other conductive structures. In some embodiments, the material of the base 200 may be silica. In other embodiments, the base 200 may also be made of silicon nitride or silicon carbide.

In some embodiments, since a metal interconnection structure is formed on a semiconductor substrate to be processed on which a source electrode, a drain electrode, and a gate electrode have been formed, the base 200 may further include an electrode 201 which is an electrical interconnection structure led out on the semiconductor substrate, and the specific material may be metal material such as metallic tungsten or metallic silver.

The width of an upper surface of the electrode 201 is greater than the width of a lower surface of the electrode 201. The upper surface of the electrode 201 is a surface in contact with the first conductive layer 202. The larger the width of the upper surface, the larger the contact area and the lower the contact resistance, which can effectively improve the conductive efficiency of the semiconductor structure.

The surface of the electrode 201 may have a protective layer (not illustrated), and the material of the protective layer may be titanium nitride, which can effectively prevent ions in the electrode 201 from diffusing outward to cause adverse effects.

In some embodiments, the material of the first conductive layer 202 may be metallic copper, and the resistivity of the metallic copper is low, so that the conductive effect of the semiconductor structure is improved while the production cost of the semiconductor structure is reduced. In other embodiments, the material of the first conductive layer may also be metallic aluminum or metallic cobalt.

In some embodiments, the first conductive layer 202 may be formed directly with a copper sputtering process. In other embodiments, the first conductive layer may also be formed by a chemical vapor deposition process.

In some embodiments, a portion of the first conductive layer 202 is located within the base 200, and the remaining portion of the first conductive layer 202 protrudes above the base 200, this is because part of the first conductive layer 202 is required to be exposed from the base 200 due to contact between the subsequently formed barrier layer 204 and part of the sidewall of the first conductive layer 202.

Specifically, in a direction perpendicular to an upper surface of the base 200, a thickness ratio of the remaining portion of the first conductive layer 202 protruding from the base 200 to the portion of the first conductive layer 202 located within the base 200 is 1:1 to 1:2.

Since the portion of the first conductive layer 202 is located within the base 200, the base 200 also has a fixing effect on the first conductive layer 202. The thickness ratio of the remaining portion of the first conductive layer 202 protruding from the base 200 to the portion of the first conductive layer 202 located within the base 200 is kept within the above range, so that a sufficient contact area is reserved for the barrier layer 204 while ensuring the fixing effect of the base 200 on the first conductive layer 202.

The first conductive layer 202 is not only in contact with the upper surface of the electrode 201 but also with part of the sidewall of the electrode 201. The contact area between the first conductive layer 202 and the electrode 201 is large, so that the contact resistance between the first conductive layer 202 and the electrode 201 is low, and the conductive effect of the semiconductor structure is further improved.

The surface of the first conductive layer 202 may also have a protective layer (not illustrated) that prevents ions in the first conductive layer 202 from diffusing outward, and the material of the protective layer on the surface of the first conductive layer 202 may be tantalum metal or tantalum nitride.

In some embodiments, the semiconductor structure may further include: a stop layer 203 located on an upper surface of the base 200 and between the base 200 and the barrier layer 204.

The material of the stop layer 203 may be silicon nitride or silicon carbonitride. Since a portion of the base 200 is required to be removed after the first conductive layer 202 is formed to enable part of the first conductive layer 202 is located above the base 200, the stop layer 203 may be served as an etching stop layer in the process of removing the portion of the base 200 to effectively prevent over-etching.

In some embodiments, the barrier layer 204 may be located not only on the sidewall of the first conductive layer 202 protruding above the base 200, but also in contact with a portion of the upper surface of the first conductive layer 202. The contact area between the barrier layer 204 and the first conductive layer 202 is large, which helps to improve the adhesion and fixing effect of the barrier layer 204 to the first conductive layer 202. Since the barrier layer 204 has more than one contact surface with the first conductive layer 202, when the first conductive layer 202 is subjected to a process stress in a certain direction, even if the barrier layer 204 in contact with one surface of the first conductive layer 202 cannot exert the adhesion effect, the barrier layer 204 in contact with another surface of the first conductive layer 202 can exert the adhesion effect, thereby ensuring that the barrier layer 204 and the first conductive layer 202 have a better adhesion effect in most cases.

In some embodiments, the barrier layer 204 may be a two-layer structure including a first barrier layer 214 and a second barrier layer 224 stacked in sequence, and the material of the first barrier layer 214 is different from the material of the second barrier layer 224. The second barrier layer 224, the first barrier layer 214 and the first conductive layer 202 enclose a hole. The second conductive layer 206 fills the hole. In other embodiments, the barrier layer may also be a single layer structure.

Since the second barrier layer 224, the first barrier layer 214 and the first conductive layer 202 enclose a hole, the area of the upper surface of the first conductive layer 202 exposed to contact with the second conductive layer 206 is large, which is conducive to increasing the contact area between the first conductive layer 202 and the second conductive layer 206, reducing the contact resistance, and further improving the conductive effect of the entire semiconductor structure. Due to the existence of the hole, the first barrier layer 214 and the second barrier layer 224 may form a snap-like structure in which the second conductive layer 206 filling the hole is stuck. During a subsequent process, the first barrier layer 214 and the second barrier layer 224 can fix the second conductive layer 206, regardless of the process stress in any direction, to ensure that the second conductive layer 206 does not detach from the surface of the first conductive layer 202.

In some embodiments, the thickness of the first barrier layer 214 is less than the thickness of the second barrier layer 224 in a direction perpendicular to the upper surface of the first conductive layer 202.

When the first barrier layer 214 is etched to form a hole, over-etching easily occurs, resulting in fewer barrier layers 204 located on the upper surface of the first conductive layer 202. Therefore, greater thickness of the second barrier layer 224 is helpful to ensure that the upper surface of the first conductive layer 202 has a large area of barrier layer 204 even if the first barrier layer 214 is over-etched. Less thickness of the first barrier layer 214 may facilitate controlling the etching effect when the hole is formed.

In some embodiments, the thickness ratio of the first barrier layer 214 to the second barrier layer 224 may be 1:3 to 1:4 in a direction perpendicular to the upper surface of the first conductive layer 202.

Specifically, in the direction perpendicular to the upper surface of the first conductive layer 202, the thickness of the first barrier layer 214 may be 5 nm to 10 nm, specifically 6 nm, 7 nm or 8 nm. The thickness of the second barrier layer 224 may be 15 nm to 40 nm, specifically 20 nm, 25 nm or 30 nm.

Within this range, the first barrier layer 214 can ensure the adhesion effect while preventing the etching effect from being beyond control when the hole is formed due to excessive thickness. The second barrier layer 224 does not cause poor adhesion of the entire barrier layer 204 when the first barrier layer 214 is over-etched due to over-thickness.

In some embodiments, the material of the first barrier layer 214 may include silicon oxynitride or nitrogen fluoride silicon. The material of the second barrier layer 224 may include silicon nitride or silicon carbonitride. Under the same wet etching, an etching selection ratio of the first barrier layer 214 is larger than an etching selection ratio of the second barrier layer 224, which facilitates that the second barrier layer 224 is not excessively affected when the first barrier layer 214 is etched to form a hole.

In some embodiments, the material of the dielectric layer 205 may be the same as the material of the base 200 to prevent different second conductive layers 206 from being in electrical contact. The material of the dielectric layer 205 may be specifically silicon dioxide, silicon nitride, or silicon carbide.

In some embodiments, the width of the second conductive layer 206 located in the vicinity of the second barrier layer 224 is smaller than the width of the top surface of the second conductive layer 206. With this arrangement, while ensuring that the upper surface of the first conductive layer 202 has the barrier layer 204 having a large area, the area of the exposed top surface of the second conductive layer 206 subsequently used for detection or wiring is increased.

In some embodiments, the material of the second conductive layer 206 may be metallic tungsten. In other embodiments, the material of the second conductive layer may also be a metal material having a higher conductivity such as metallic silver or metallic cobalt.

The surface of the second conductive layer 206 may have a protective layer (not illustrated). The material of the protective layer may be titanium nitride, which can effectively prevent ions in the second conductive layer 206 from diffusing outward to cause adverse effects.

FIG. 3 illustrates a schematic diagram of another semiconductor structure according to an embodiment of the present disclosure.

Referring to FIG. 3, in other embodiments, the second conductive layer 206 may be in contact with the entire upper surface of the first conductive layer 202.

When the first barrier layer 214 on the top surface of the first conductive layer 202 is removed, the entire first barrier layers 214 on the upper surface of the first conductive layer 202 are removed to expose the entire upper surface of the first conductive layer 202, which is conductive to forming a maximum contact area between the first conductive layer 202 and the second conductive layer 206 and reducing the contact resistance.

In some embodiments, a barrier layer 204 may be not only in contact with a sidewall of a first conductive layer 202 protruding from a base 200, but also in contact with a sidewall of a second conductive layer 206, so that there the same barrier layer 204 are in contact with different conductive layers, which is conducive to fixing the locations of the different conductive layers by use of the barrier layer 204. In a subsequent process, the locational relationship between the different conductive layers is not easily affected by stress to form a gap which affects the performance of the semiconductor structure. Meanwhile, the contact between the barrier layer 204 and the sidewalls of the conductive layers is beneficial to increasing the contact area. The larger the contact area, the better the adhesion and fixing effect of the barrier layer 204 to the conductive layers.

Accordingly, another embodiment of the present disclosure further provides a method of forming a semiconductor structure. The semiconductor structure formed by the method of forming a semiconductor structure provided in another embodiment of the present disclosure is the same as the semiconductor structure provided in the above embodiments. A method of forming a semiconductor structure provided in another embodiment of the present disclosure will be described in detail below with reference to the accompanying drawings.

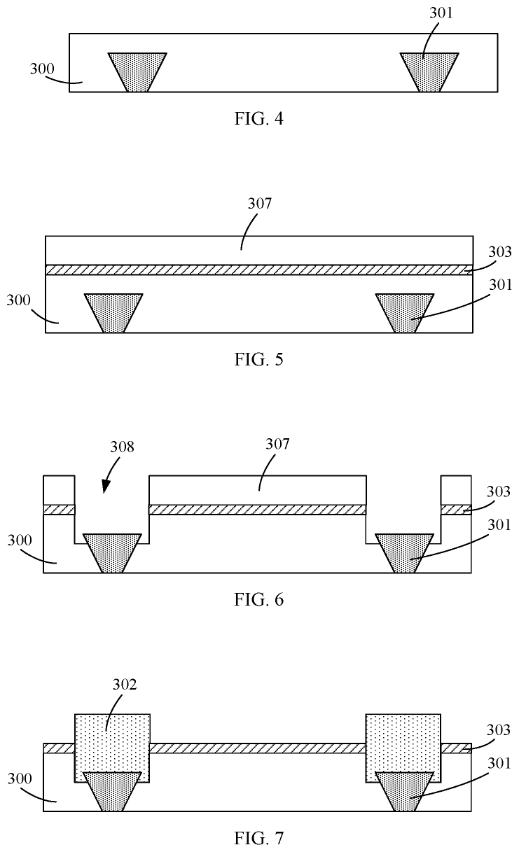

FIGS. 4-11 illustrate schematic diagrams of various operations of a method of forming a semiconductor structure according to another embodiment of the present disclosure.

Referring to FIG. 4, a base 300 is provided.

The material of the base 300 may be an isolation material for isolating the conductive layer from other conductive structures. In some embodiments, the material of the base 300 may be silica. In other embodiments, the base 300 may also be silicon nitride or silicon carbide.

In some embodiments, since a metal interconnection structure is formed on a semiconductor substrate to be processed on which a source electrode, a drain electrode, and a gate electrode have been formed, the base 300 may further include an electrode 301 which is an electrical interconnection structure led out on the semiconductor substrate, and the specific material thereof may be metal material such as metallic tungsten or metallic silver.

The width of an upper surface of the electrode 301 is greater than the width of a lower surface of the electrode 301. The upper surface of the electrode 301 is a surface in contact with the subsequently formed first conductive layer 202. The larger the width of the upper surface, the larger the contact area and the lower the contact resistance, which can effectively improve the conductive efficiency of the semiconductor structure.

Referring to FIGS. 5-7, a first conductive layer 302 is formed, a portion of the first conductive layer 302 is located within the base 300 and a remaining portion of the first conductive layer 302 protrudes above the base 300.

Specifically, referring to FIG. 5, a stop layer 303 is formed on the upper surface of the base 300.

In some embodiments, the stop layer 303 may be formed by an atomic layer deposition process, and the material of the stop layer 303 may be silicon nitride or silicon carbonitride. Since the sacrificial layer is removed after the first conductive layer is formed in order to make a portion of the first conductive layer located above the base 300 during subsequent formation of the first conductive layer, the stop layer 303 may be served as an etching stop layer in the process of removing the sacrificial layer to effectively prevent over-etching.

A sacrificial layer 307 may be formed on the base 300. Particularly, the sacrificial layer 307 may be located on the upper surface of the stop layer 303.

In some embodiments, the sacrificial layer 307 may be formed by a chemical vapor deposition process. The material of the sacrificial layer 307 is the same as that of the base 300. The same material of the base 300 and the sacrificial layer 307 is helpful to keep the rates at which the sacrificial layer 307 and the base 300 are etched to be consistent, which facilitates the implementation of the process.

Referring to FIG. 6, the sacrificial layer 307 and base 300 are patterned to form a first trench 308 within sacrificial layer 307 and base 300.

In some embodiments, part of the sacrificial layer 307, part of the stop layer 303 and part of the base 300 may be removed by wet etching, and a first trench 308 is formed for subsequent formation of a first conductive layer.

Referring to FIG. 7, a first conductive layer 302 is formed to fill a first trench 308 (referring to FIG. 6). The sacrificial layer 307 (referring to FIG. 6) is removed until the stop layer 303 is exposed.

In some embodiments, the first conductive layer 302 may be formed by a chemical vapor deposition process. The sacrificial layer 307 may be removed by wet etching, and the stop layer 303 is served as an etching stop layer.

In some embodiments, the material of the first conductive layer 302 may be metallic copper. The resistivity of the metallic copper is low, so that the conductive effect of the semiconductor structure is improved while the production cost of the semiconductor structure is reduced. In other embodiments, the material of the first conductive layer may also be metallic aluminum or metallic cobalt.

In some embodiments, a portion of the first conductive layer 302 is located within the base 300, and a remaining portion of the first conductive layer 302 protrudes above the base 300, this is because part of the first conductive layer 302 is required to be exposed from the base 300 due to contact between the subsequently formed barrier layer 304 and a portion of the sidewall of the first conductive layer 302.

The first conductive layer 302 is not only in contact with the upper surface of the electrode 301 but also with a portion of the sidewall of the electrode 301. The contact area between the first conductive layer 302 and the electrode 301 is large, so that the contact resistance between the first conductive layer 302 and the electrode 301 is low, and the conductive effect of the semiconductor structure is further improved.

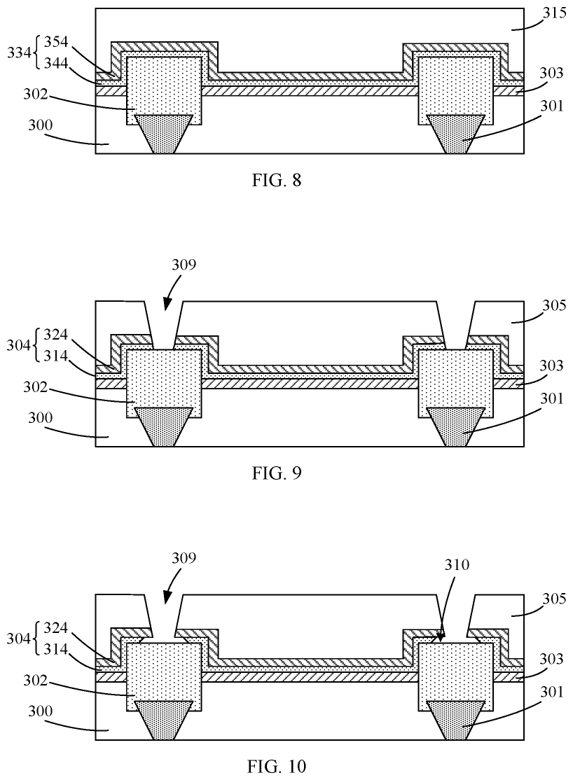

Referring to FIGS. 8-11, a barrier layer 304 on the base 300 and at least on the sidewall of the first conductive layer 302 protruding from the base 300 is formed. A dielectric layer 305 covering the surface of the barrier layer 304 is formed. A second conductive layer 306 penetrating the dielectric layer 305 and the barrier layer 304 is formed, the second conductive layer 306 is in contact with the sidewall of the barrier layer 304, and the second conductive layer 306 is in contact with at least a portion of the upper surface of the first conductive layer 303.

A barrier layer 304 is not only in contact with a sidewall of a first conductive layer 302 protruding from a base 300, but also in contact with a sidewall of a second conductive layer 306, so that there the same barrier layer 304 is in contact with different conductive layers, which is conducive to fixing the locations of different conductive layers by use of the barrier layer 304. In a subsequent process, the location relationship between the different conductive layers is not easily affected by stress to form a gap which affects the performance of the semiconductor structure. Meanwhile, the contact between the barrier layer 304 and the sidewalls of the conductive layers is beneficial to increasing the contact area. The larger the contact area, the better the adhesion and fixing effect of the barrier layer 304 to the conductive layers.

Specifically, referring to FIG. 8, an initial barrier layer 334 is formed that covers the exposed surface of the first conductive layer 302 and that is located on the base 300. An initial dielectric layer 315 is formed that covers the upper surface of the initial barrier layer 334.

In some embodiments, the initial barrier layer 304 may include an initial first barrier layer 344 and an initial second barrier layer 354. An atomic deposition process may be adopted to form the initial first barrier layer 344 on the base 300 and on a surface of the first conductive layer 302 protruding from the base 300, and then an atomic deposition process may be adopted to form the initial second barrier layer 354 on the surface of the initial first barrier layer 344. The initial dielectric layer 315 may be formed by a chemical vapor deposition process.

In some embodiments, the material of the initial first barrier layer 344 may be different from the material of the initial second barrier layer 354, and the material of the initial first barrier layer 344 may include silicon oxynitride or nitrogen fluoride silicon. The material of the initial second barrier layer 354 may include silicon nitride or silicon carbonitride. Under the same wet etching, an etching selection ratio of the initial first barrier layer 344 is larger than an etching selection ratio of the initial second barrier layer 354, which facilitates that the second barrier layer is not excessively affected when the hole is formed in the subsequent etching of the first barrier layer.

In some embodiments, the material of the initial dielectric layer 315 may be the same as the material of the base 300, and different second conductive layers formed subsequently may be prevented from being in electrical contact with each other. The material of the initial dielectric layer 315 may be specifically silicon dioxide, silicon nitride, or silicon carbide.

Referring to FIG. 9, the initial dielectric layer 315 and the initial barrier layer 334 are patterned until at least a portion of the surface of the first conductive layer 302 is exposed to form the second trench 309. The remaining portion of the initial dielectric layer 315 is served as the dielectric layer 305 and the remaining portion of the initial barrier layer 334 is served as the barrier layer 304.

The barrier layer 304 may include a first barrier layer 314 and a second barrier layer 324 stacked in sequence, and the materials of the first barrier layer 314 and the second barrier layer 324 may be different.

In some embodiments, the thickness of the first barrier layer 314 is less than the thickness of the second barrier layer 324 in a direction perpendicular to the upper surface of the first conductive layer 302.

When the first barrier layer 314 is subsequently etched to form a hole, an over-etching phenomenon easily occurs, resulting in fewer barrier layers 304 located on the upper surface of the first conductive layer 302. Therefore, greater thickness of the second barrier layer 324 may help to ensure that the upper surface of the first conductive layer 302 has a large area of barrier layer 304 even if the first barrier layer 314 is over-etched. Less thickness of the first barrier layer 314 may facilitate controlling the etching effect when the hole is formed.

In some embodiments, the thickness ratio of the first barrier layer 314 to the second barrier layer 324 may be 1:3 to 1:4 in a direction perpendicular to the upper surface of the first conductive layer 302.

Specifically, in the direction perpendicular to the upper surface of the first conductive layer 302, the thickness of the first barrier layer 314 may be 5 nm to 10 nm, specifically 6 nm, 7 nm or 8 nm. The thickness of the second barrier layer 324 may be 15 nm to 40 nm, specifically 20 nm, 25 nm or 30 nm.

Within this range, the first barrier layer 314 may ensure the adhesion effect while preventing the etching effect from being beyond control when the hole is formed due to excessive thickness. The second barrier layer 324 does not cause poor adhesion of the entire barrier layer 304 when the first barrier layer 314 is over-etched due to over-thickness.

Referring to FIG. 10, after forming the second trench 309, the method may further include: performing wet etching on the first barrier layer 314 exposed from the second trench 309 so that the second barrier layer 324, the first conductive layer 302 and the remaining portion of the first barrier layer 314 enclose the hole 310.

Since the second barrier layer 324, the first barrier layer 314 and the first conductive layer 302 enclose a hole 310, the area of the upper surface of the first conductive layer 302 exposed to contact with the second conductive layer 306 is large, which is conducive to increasing the contact area of the first conductive layer 302 and the second conductive layer 306, reducing the contact resistance, and further improving the conductive effect of the entire semiconductor structure. Because of existence of the hole 310, the first barrier layer 314 and the second barrier layer 324 may form a snap-like structure in which the second conductive layer 306 filling the hole 310 is stuck. During a subsequent process, the first barrier layer 314 and the second barrier layer 324 fix the second conductive layer 306, regardless of the process stress in any direction, to ensure that the second conductive layer 306 does not detach from the surface of the first conductive layer 302.

In some embodiments, the wet etching has a larger etching selection ratio for the first barrier layer 314 than for the second barrier layer 324. Therefore, the second barrier layer 324 will not be affected during the wet etching.

In some embodiments, an etching solution selected for the wet etching may include an aqueous hydrofluoric acid solution. Where the mass ratio of hydrofluoric acid to water is 1:50-1:100, which specifically may be 1:60, 1:70 or 1:80.

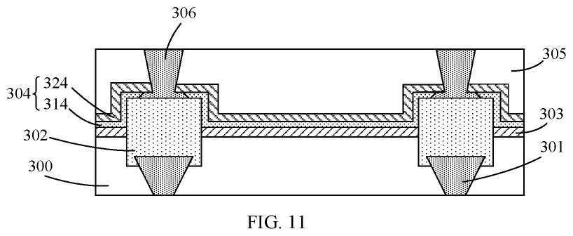

Referring to FIG. 11, a second conductive layer 306 is formed that fills the second trench 309 (referring to FIG. 10), and the second conductive layer 306 also fills the hole 310 (referring to FIG. 10).

In some embodiments, the width of the second conductive layer 306 located in the vicinity of the second barrier layer 324 may be smaller than the width of the top surface of the second conductive layer 306. With this arrangement, while ensuring that the upper surface of the first conductive layer 302 has the barrier layer 304 with a large area, the area of the top surface exposed from the second conductive layer 306 is increased for subsequent detection or wiring.

In some embodiments, the second conductive layer 306 may be formed by a chemical vapor deposition process, and the material of the second conductive layer 306 may be metallic tungsten. In other embodiments, the material of the second conductive layer may also be a metal material having a higher conductivity such as metallic silver or metallic cobalt.

In some embodiments, a formed barrier layer 304 may be not only in contact with a sidewall of a first conductive layer 302 protruding from a base 300, but also in contact with a sidewall of a second conductive layer 306, so that the same barrier layer 304 are in contact with different conductive layers, which is conducive to fixing the locations of the different conductive layers by use of the barrier layer 304. In a subsequent process, the location relationship between the different conductive layers is not easily affected by stress to form a gap which affects the performance of the semiconductor structure. Meanwhile, the contact between the barrier layer 304 and the sidewall of the conductive layer is beneficial to increasing the contact area. The larger the contact area, the better the adhesion and fixing effect of the barrier layer 304 to the conductive layer.

Another embodiment of the present disclosure further provides a memory including a semiconductor structure as provided in the above embodiments.

A barrier layer in a semiconductor structure included in a memory provided by some embodiments is not only in contact with a sidewall of a first conductive layer protruding from a base, but also in contact with a sidewall of a second conductive layer, so that the same barrier layer is in contact with different conductive layers, which is conducive to fixing the locations of the different conductive layers by use of the barrier layer. In a subsequent process, the location relationship between the different conductive layers is not easily affected by stress to form a gap which affects the performance of the semiconductor structure. Meanwhile, the contact between the barrier layer and the sidewalls of the conductive layers is beneficial to increasing the contact area. The larger the contact area, the better the adhesion and fixing effect of the barrier layer to the conductive layer.

Those of ordinary skill in the art will appreciate that the above embodiments are specific embodiments for realizing the present disclosure, and in practical application, various changes may be made thereto in form and detail without departing from the spirit and scope of the present disclosure. Any person skilled in the art may make his or her own changes and modifications without departing from the spirit and scope of the present disclosure. Therefore, the protection scope of the present disclosure shall be subject to the scope defined in the claims.

In the semiconductor structure in embodiments of the present disclosure, a barrier layer is not only in contact with a sidewall of a first conductive layer protruding from a base, but also in contact with a sidewall of a second conductive layer, so that the same barrier layer is in contact with different conductive layers, which is conducive to fixing the locations of the different conductive layers by use of the barrier layer. In a subsequent process, the location relationship between the different conductive layers is not easily affected by stress to form a gap. Meanwhile, the contact between the barrier layer and the sidewall of the conductive layer is beneficial to increasing the contact area. The larger the contact area, the better the adhesion and fixing effect of the barrier layer to the conductive layer.

What is claimed is:

1. A semiconductor structure comprising:
a base;
a first conductive layer, having a portion located within the base and a remaining portion protruding above the base;
a barrier layer on the base, the barrier layer being at least on a sidewall of the first conductive layer protruding from the base;
a dielectric layer on the barrier layer; and
a second conductive layer, penetrating the dielectric layer and the barrier layer, being in contact with the sidewall of the barrier layer, and being in contact with at least a portion of an upper surface of the first conductive layer.

2. The semiconductor structure according to claim 1, wherein the barrier layer comprises a first barrier layer and a second barrier layer stacked in sequence, and a material of the first barrier layer and a material of the second barrier layer are different;
the second barrier layer, the first barrier layer and the first conductive layer enclose a hole;
the second conductive layer fills the hole.

3. The semiconductor structure according to claim 2, wherein a thickness of the first barrier layer is less than a thickness of the second barrier layer in a direction perpendicular to the upper surface of the first conductive layer.

4. The semiconductor structure according to claim 3, wherein a thickness ratio of the first barrier layer to the second barrier layer is 1:3 to 1:4 in the direction perpendicular to the upper surface of the first conductive layer.

5. The semiconductor structure according to claim 3, wherein the thickness of the first barrier layer is 5 nm to 10 nm and the thickness of the second barrier layer is 15 nm to 40 nm in the direction perpendicular to the upper surface of the first conductive layer.

6. The semiconductor structure according to claim 2, wherein the material of the first barrier layer comprises silicon oxynitride or nitrogen fluoride silicon, and the material of the second barrier layer comprises silicon nitride or silicon carbonitride.

7. The semiconductor structure according to claim 2, wherein the second conductive layer is in contact with an entire upper surface of the first conductive layer.

8. The semiconductor structure according to claim 1, wherein a thickness ratio of the remaining portion of the first conductive layer protruding from the base to the portion of the first conductive layer located within the base is 1:1 to 1:2 in a direction perpendicular to an upper surface of the base.

9. The semiconductor structure according to claim 1, further comprising: a stop layer located on an upper surface of the base and located between the base and the barrier layer.

10. A method of forming a semiconductor structure, comprising:
providing a base;
forming a first conductive layer, the first conductive layer having a portion located within the base and a remaining portion protruding above the base;
forming a barrier layer, the barrier layer being on the base and at least on a sidewall of the first conductive layer protruding from the base;
forming a dielectric layer, the dielectric layer covering a surface of the barrier layer; and
forming a second conductive layer, the second conductive layer penetrating the dielectric layer and the barrier layer, being in contact with the sidewall of the barrier layer and being in contact with at least a portion of an upper surface of the first conductive layer.

11. The method of forming a semiconductor structure according to claim 10, wherein said forming the first conductive layer comprises:
forming a sacrificial layer on the base;
patterning the sacrificial layer and the base, forming a first trench within the sacrificial layer and the base;
forming the first conductive layer filling the first trench; and
removing the sacrificial layer.

12. The method of forming a semiconductor structure according to claim 11, wherein before said forming the sacrificial layer on the base, the method further comprises: forming a stop layer on an upper surface of the base;
wherein during removing of the sacrificial layer, removing of the sacrificial layer continues until the stop layer is exposed.

13. The method of forming a semiconductor structure according to claim 10, wherein said forming the barrier layer, the dielectric layer and the second conductive layer comprises:
forming an initial barrier layer, the initial barrier layer covering an exposed surface of the first conductive layer and being located on the base;
forming an initial dielectric layer covering an upper surface of the initial barrier layer;
patterning the initial dielectric layer and the initial barrier layer until at least a portion of a surface of the first conductive layer is exposed to form a second trench, wherein a remaining portion of the initial dielectric layer serves as the dielectric layer and a remaining portion of the initial barrier layer serves as the barrier layer; and
forming the second conductive layer filling the second trench.

14. The method of forming a semiconductor structure according to claim 13, wherein the barrier layer comprises a first barrier layer and a second barrier layer stacked in sequence, and a material of the first barrier layer and a material of the second barrier layer are different;
after forming the second trench, the method further comprises:
performing wet etching on a portion of the first barrier layer exposed from the second trench to make the second barrier layer, the first conductive layer and a remaining portion of the first barrier layer enclose a hole;
wherein in a process of forming the second conductive layer, the second conductive layer is taken to fill the hole.

15. The method of forming a semiconductor structure according to claim 14, wherein an etching selection ratio of the wet etching to the first barrier layer is greater than an etching selection ratio of the wet etching to the second barrier layer.

16. The method of forming a semiconductor structure according to claim 15, wherein an etching solution selected for the wet etching comprises an aqueous hydrofluoric acid solution.

17. A memory comprising a semiconductor structure, the semiconductor structure comprising:
a base;
a first conductive layer, having a portion located within the base and a remaining portion protruding above the base;
a barrier layer on the base, the barrier layer being at least on a sidewall of the first conductive layer protruding from the base;
a dielectric layer on the barrier layer; and
a second conductive layer, penetrating the dielectric layer and the barrier layer, being in contact with the sidewall of the barrier layer, and being in contact with at least a portion of an upper surface of the first conductive layer.

18. The memory according to claim 17, wherein the barrier layer comprises a first barrier layer and a second barrier layer stacked in sequence, and a material of the first barrier layer and a material of the second barrier layer are different;
the second barrier layer, the first barrier layer and the first conductive layer enclose a hole;
the second conductive layer fills the hole.

19. The memory according to claim 18, wherein a thickness of the first barrier layer is less than a thickness of the second barrier layer in a direction perpendicular to the upper surface of the first conductive layer.

20. The memory according to claim 19, wherein a thickness ratio of the first barrier layer to the second barrier layer is 1:3 to 1:4 in the direction perpendicular to the upper surface of the first conductive layer.
